(19) United States
(12) Patent Application Publication
(10) Pub. No.: US 2003/0023913 A1
(43) Pub. Date: Jan. 30, 2003

(54) Testing device of semiconductor integrated circuit and test method therefor

(75) Inventors: Yukikazu Matsuo, Hyogo (JP); Yoshihiro Nagura, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/084,338

(22) Filed: Feb. 28, 2002

(30) Foreign Application Priority Data
Jul. 25, 2001 (JP) 2001-224899

(51) Int. Cl. G01R 31/28

(52) U.S. Cl. 714/727; 714/733

(57) ABSTRACT

In the testing device of a semiconductor integrated circuit, each of the logics is provided with the JTAG circuit includes: a boundary scan register that executes a test of the logic in accordance with a test data input and stores a test result, a data register, a pseudo bypass register having a bypassing function of the test data input, a first selector connected to the data register and the pseudo bypass register, which selectively takes out outputs of the registers, a bypass register having the bypassing function of the test data input, an instruction register for giving an operation command, and a second selector connected to the boundary scan register, the first selector, the bypass register, and the instruction register, which is selectively controlled by the instruction register. In this construction, the output from the second selector of a specific logic is connected to the input of another logic.

### BACKGROUND OF THE INVENTION

1. Field of the Invention

The present invention relates to a testing device of a semiconductor integrated circuit that specifically includes more than one different logics, such as a memory core, and incorporates a JTAG circuit (circuit conforming to the Joint Test Action Group standard), and a method of testing the same.

2. Background Art

FIG. 9 is a block diagram illustrating the conventional testing device of a semiconductor integrated circuit that incorporates the JTAG circuit. The semiconductor integrated circuit mounted on the same chip includes two different logics (logic 1 and logic 2), and the logics each include the JTAG circuits each.

In the figure, reference numeral 11 is integrated into the logic 1, and denotes a Boundary Scan Register (hereunder, referred to as BSR) that composes a major part of the JTAG circuit, which has an equivalent function to the conventional test probe, and stores the test result of the logic 1. Reference numeral 12 denotes a Data Register (hereunder, referred to as DR) in the JTAG circuit, and reference numeral 13 a Bypass Register (hereunder, referred to as BR), which bypasses the test data input to the output, thus forming the shortest route.

Reference numeral 14 denotes an Instruction Register (hereunder, referred to as IR), which reads and decodes the command bits from the well-known TAP (Test Access Port) controller not illustrated.

Reference numeral 15 denotes a selector connected to the foregoing registers each, which is selected and controlled by the IR 14 to send out either one of the register outputs. Reference numeral 21 denotes a BSR integrated into the logic 2, 22 a DR, 23 a BR, 24 an IR, and 25 a selector, and any of them has the same configuration as that of the logic 1.

Here, TDI signifies a test data input signal to the JTAG circuit, and TDO a test data output signal from the JTAG circuit, and the output from the selector 15 of the logic 1 is the input signal to the logic 2.

The operation of testing each of the logics twice and reading the test results in this configuration will be described with reference to a flow chart shown in FIG. 10.

First, in Step S1 the test mode of the logic 1 is set. Next, in Step S2 the first test of the logic 1 is executed, and in Step S3 the test result in the BSR 11 is stored. Then, in Step S4 the test result of the first test stored in the BSR 11 is read out. This readout signal is inputted to the logic 2 by way of the selector 15, and outputted to the test data output TDO by way of the BR 23 and the selector 25 of the logic 2. Here, the selector 15 of the logic 1 is set to select the test result of the BSR 11 by the IR 14; and in the logic 2, the selector 25 is set to select the BR 23 by the IR 24.

And then, in Step S5 the second test of the logic 1 is executed, and in Step S6 the test result in the BSR 11 is stored.

In Step S7, the test result of the second test is read, and in the same manner as the first test, the test result signal from the BSR 11 is outputted to the TDO of the logic 2.

Next, in Step S8 the test mode of the logic 2 is set, and in Step S9, the first test of the logic 2 is carried out. In Step S10 the test result in the BSR 21 is stored, and in Step S11, the test result is read out.

The readout signal is outputted from the BSR 21 to the TDO by way of the selector 25.

Also in this case, the selector 25 is set to select the test result of the BSR 21 by the IR 24. And then, in Step S12 the second test of the logic 2 is carried out, and in Step 13 the test result in the BSR 21 is stored.

Next, in Step S14 the test result of the BSR 21 is read out. The readout signal is outputted to the TDO by way of the selector 25, in the same manner as the first test, and the test is completed in Step S15.

The conventional in-circuit test of a semiconductor integrated circuit by the JTAG circuit is carried out as above. And, in case of the two logics 1, 2 as the testing objects being simultaneously in the test, when the test result is read from the BSR 11 in one logic, for example, in the logic 1, the BR 23 in the logic 2 is made to function. However, the BR 23 or BR 13 is made to be valid, when the IR 24 or IR 14 of the JTAG circuit is all “1”. Therefore, the logic that set the BR 23 or BR 13 has to slip out of the test mode (for example, RUNBIST) set by the IR 24 or IR 14, whereby the simultaneous testing of the logics accompanied with plural times readouts of the test results becomes impossible, which is disadvantageous.

### SUMMARY OF THE INVENTION

The present invention has been made in view of the above circumstances, and an object of the invention is to provide a testing device and a test method that attains the bypassing function being not influenced by the state of the Instruction Register.

According to one aspect of the present invention, there is provided a testing device of a semiconductor integrated circuit having more than one different logics and JTAG circuits built in, which executes an in-circuit test of the logics. The JTAG circuit includes a boundary scan register that executes a test of the logic in accordance with a test data input and stores a test result; a data register; a pseudo bypass register having a bypassing function of the test data input; a first selector connected to the data register and the pseudo bypass register, which selectively takes out outputs of the registers; a bypass register having a bypassing function of the test data input; an instruction register for giving an operation command; and a second selector that is connected to the boundary scan register, the first selector, the bypass register, and the instruction register, which is selectively controlled by the instruction register. The JTAG circuits are provided to each of the logics, and the output from the second selector of a specific logic is an input of another logic.

According to another aspect of the present invention, there is provided a testing device of a semiconductor integrated circuit having more than one different logics and JTAG circuits built in, which executes an in-circuit test of the logics. Each of the logics is provided with: a control block including a boundary scan register that executes a test of the logic in accordance with a test data input and stores a test result, a data register, a pseudo bypass register having a bypassing function of the test data input, and a first selector connected to each of the registers, which selectively takes out outputs of the registers; and a bypass register; an instruction register; and a second selector that is connected to these registers and the first selector, which is selectively controlled by the instruction register. The output from the second selector of a specific logic is an input of another logic.

According to another aspect of the present invention, there is provided a testing device of a semiconductor integrated circuit having more than one different logics and JTAG circuits built in, which executes an in-circuit test of the logics. Each of the logics is provided with: a control block including a boundary scan register that executes a test of the logic in accordance with a test data input and stores a test result, a data register, a pseudo bypass register having a bypassing function of the test data input, and a first selector connected to each of the registers, which selectively takes out outputs of the registers; a bypass register and an instruction register that are common to each of the control blocks; and a second selector connected to the each control block, the bypass register and the instruction register, which is selectively controlled by the instruction register. The output from the first selector of a specific control block is an input of another control block.

According to another aspect of the present invention, there is provided a test method of a semiconductor integrated circuit, which carries out an in-circuit test thereof by a testing device thereof described above.

The testing device and test method of a semiconductor integrated circuit relating to the invention provides each of the logics with the JTAG circuit including: the BSR that executes a test of the logic in accordance with a test data input and stores a test result, the DR, the TR having a bypassing function of the test data input, the first selector connected to the DR and TR, which selectively takes out the outputs of the registers, a BR having a bypassing function of the test data input, the IR for giving an operation command, and the second selector that is connected to the BSR, the first selector, the BR, and the IR, which is selectively controlled by the IR, in which the output from the second selector of a specific logic is connected to the input of another logic, whereby, the bypassing function can be implemented which is not influenced by the state of the IR.

Further, it is possible to carry out the test without setting the test mode repeatedly after using the bypassing function, thus leading to simplification of the test flow and accordingly a simultaneous testing of plural logics accompanied with plural times readouts of the test results becomes possible, and whereby the time for testing can be shortened.

Also, the testing device and test method of a semiconductor integrated circuit relating to the invention includes a selector on the input of the TR, whereby the test data input to be bypassed and arbitrary information can be inputted selectively. Information unique to the logic, for example, a pass or fail signal of the memory core can be added, and the information unique to the memory core can be read out at the same time of reading the output from the BSR.

Further, to configure the TR with plural bits will attain N-fold information.

Further, in the testing device and test method of a semiconductor integrated circuit relating to the invention, each of the logics is provided with: a control block including the BSR that executes a test of the logic in accordance with a test data input and stores a test result, the DR, the TR having a bypassing function of the test data input, and the first selector connected to each of the registers, which selectively takes out outputs of the registers; the BR; the IR that are common to each of the control blocks; and the second selector connected to each control block, the BR and IR, which is selectively controlled by the IR, in which the output from the first selector of a specific control block is the input of another control block, whereby the JTAG circuit is configured. Thus, one JTAG circuit will be able to carry out a simultaneous testing of plural logics.

Other and further objects, features and advantages of the invention will appear more fully from the following description.

### BRIEF DESCRIPTION OF THE DRAWINGS

FIG. 1 is a block diagram of the first embodiment.

FIG. 2 is a flow chart of the first embodiment.

FIG. 3 is a block diagram illustrating the configuration of the TR and that constitute the major part of the second embodiment, and the signal paths to these components.

FIGS. 4A to 4F are waveforms in correspondence with the mode transition of the TAP controller to illustrate the third embodiment.

FIG. 5 is a block diagram illustrating the configuration of the TR that constitute the major part of the third embodiment, and the signal paths to these components.

FIGS. 6A to 6H are waveforms in correspondence with the mode transition of the TAP controller to illustrate the third embodiment.

FIG. 7 is a block diagram to illustrate the configuration of the fourth embodiment.

FIG. 8 is a block diagram to illustrate the configuration of the fourth embodiment.

FIG. 9 is a block diagram illustrating the conventional testing device of a semiconductor integrated circuit that incorporates the JTAG circuit.

FIG. 10 is a flow chart of the related art.

### DETAILED DESCRIPTION OF THE PREFERRED EMBODIMENTS

First Embodiment

The first embodiment of the invention will now be described with reference to the drawings.

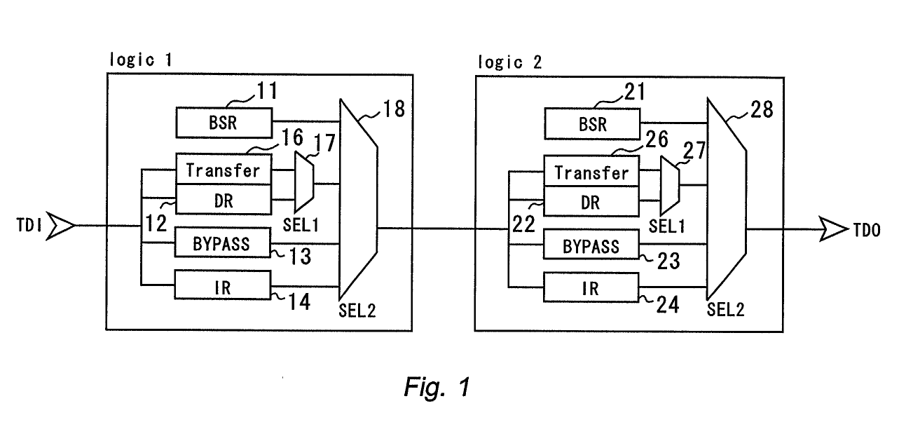

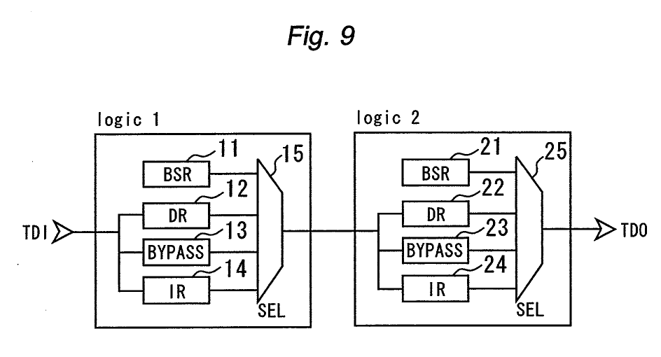

FIG. 1 is a block diagram of the first embodiment, in which the same or the equivalent parts to FIG. 9 are given the same symbols to omit the explanations. The difference from FIG. 9 lies in that the first embodiment includes Transfer Registers in replacement of the BR 13 and 23, and the DR 12 and 22 controls the TR 16 and 26. In FIG. 1, 16 signifies a transfer register (TR) that constitutes the JTAG circuit of the logic 1, which assumes the same configuration as the BR 13, and has the function to bypass the test data input signal TD1 to the output.

Reference numeral 17 signifies a first selector that is connected to the TR 16 and the DR 12, which is selectively controlled and selected by the DR 12.

Also, 18 signifies a second selector that is connected to the BSR 11, the output terminal of the first selector 17, the BR 13, and the IR 14, which is, in the same manner as in FIG. 9, selectively controlled by the IR 14, and the output of the second selector is the input signal to the logic 2.

Further, 26 signifies the TR, 27 a first selector, 28 a second selector incorporated into the logic 2; and these are configured in the same manner as those in the logic 1, and the output of the second selector 28 is the test data output signal TDO.

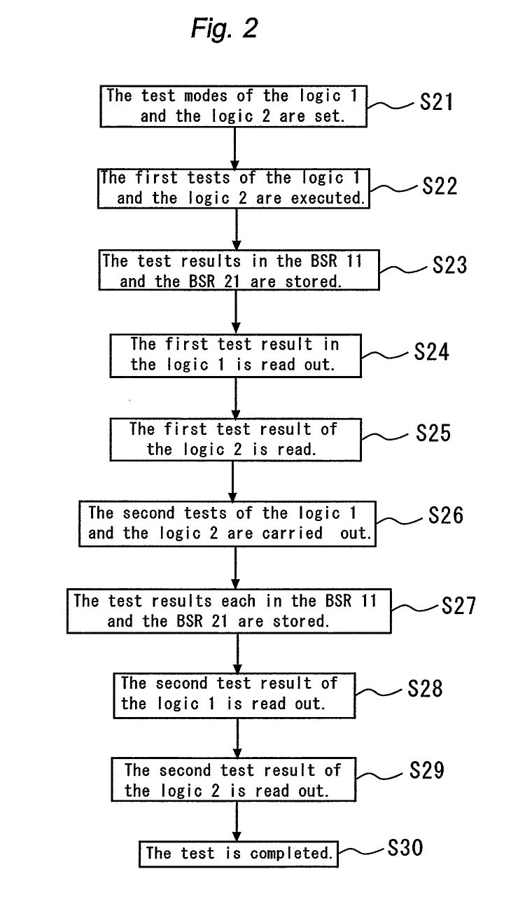

With this configuration, the operation of testing each of the logics twice and reading the test result will be described with reference to the flow chart shown in FIG. 2.

First, in Step S21 the test modes of the logic 1 and the logic 2 are set. Next, in Step S22 the first tests of the logic 1 and the logic 2 are executed, and in Step S23 each test results are stored into the BSR 11 and the BSR 21. Then, in Step S24 the first test result in the logic 1 is read out, which is stored in the BSR 11. This readout signal is inputted to the logic 2 by way of the second selector 18 that is selecting the BSR 11, according to the IR 14.

In the logic 2, the DR 22 makes the first selector 27 select the TR 26, and the IR 24 makes the second selector 28 select the output from the first selector 27. Therefore, the test result signal from the logic 1 is outputted to the test data output TDO by way of the TR 26, the first selector 27, and the second selector 28 of the logic 2.

And then, in Step S25 the first test result of the logic 2 is read, which is stored in the BSR 21. At this moment, since the second selector 28 is selecting the BSR 21 according to the IR 24 in the logic 2, the readout signal is outputted to the test data output TDO by way of the second selector 28.

Thereafter, in Step S26 the second tests of the logic 1 and the logic 2 are carried out, and in Step S27 each test results are stored into the BSR 11 and the BSR 21. Then, in Step S28 the second test result of the logic 1 is read out, and the test result signal from the BSR 11 is outputted to the TDO of the logic 2 by way of the same route as that of the first test.

Also, in Step S29 the second test result of the logic 2 is read out, and the test result signal from the BSR 21 is outputted to the TDO by way of the same route as that of the first test, and in Step S30 the test is completed.

Thus, in this embodiment, since the DR 12 and 22 controls to select the TR 16 and 26, respectively, it is possible to achieve the bypassing function that is not influenced by the state of the IR 14, or the IR 24.

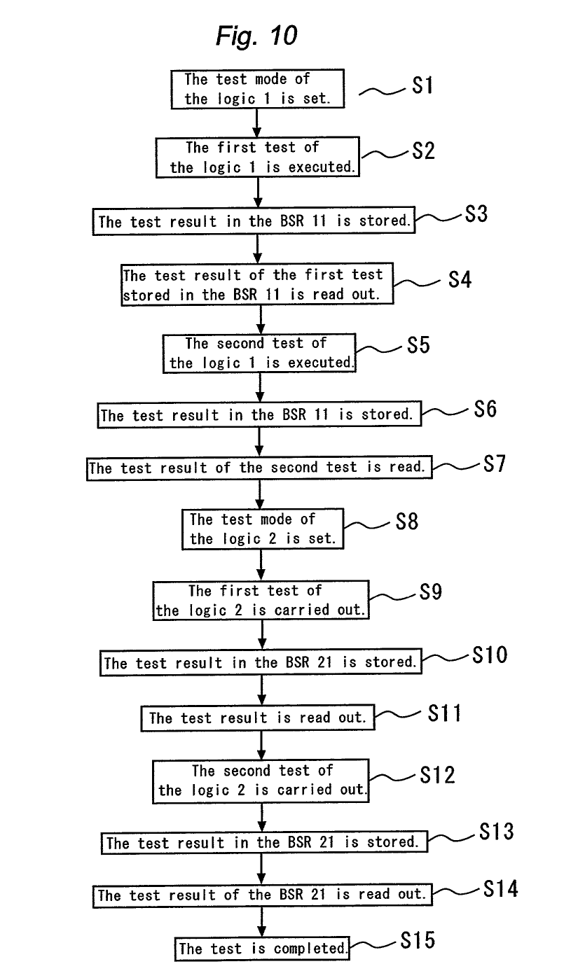

Further, in the conventional testing device as shown in FIG. 9, since the IR 14 and 24 selectively controls the BR 13 and 23, at the reading of the test result of the logic 1, when carrying out the test of the logic 2 after bringing the BR 23 of the logic 2 into function, it has been necessary to set the test mode repeatedly, as shown in the Step S8 in FIG. 10. However, since this embodiment utilizes the bypassing function of the TR 16 and 26, the logic 2 will not slip out of the test mode, thus leading to simplification of the test flow.

Therefore, as shown in the flow chart in FIG. 2, a simultaneous testing of plural logics accompanied with plural times readouts of the test results becomes possible, and the time for testing can be shortened.

Second Embodiment

Now, the second embodiment of the invention will be explained with reference to the drawings.

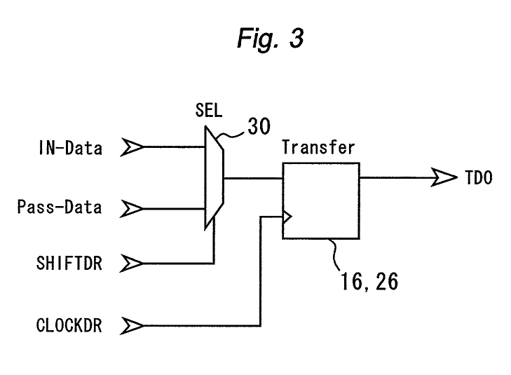

FIG. 3 is a block diagram illustrating the configuration of the TR 16 and 26 that constitute the major part of the second embodiment, and the signal paths to these components.

In FIG. 3, 16, 26 denote the TR 16 of the logic 1, and the TR 26 of the logic 2, respectively. Reference numeral 30 denotes the third selector provided on the input of the TR 16 or the TR 26, and a Pass-Data being one input of the third selector 30 is directly connected to the test data input TDI in FIG. 1, to which the test data to be bypassed is inputted. An IN-Data being the other input is an input terminal to receive arbitrary information in each of the logics, such as, a pass or fail signal of the memory core. These input are selectively controlled and selected by a SHIFT DR signal of the TAP controller not illustrated. That is, the information unique to each of the logics can be added to the TR 16 and 26 by way of the IN-Data.

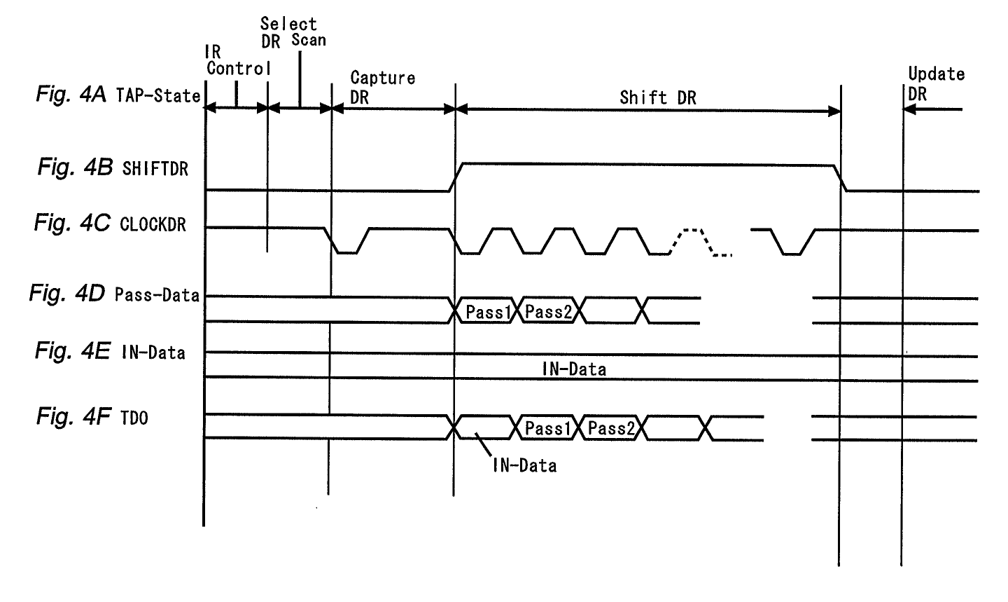

FIG. 4 illustrates waveforms in correspondence with the mode transition of the TAP controller. As shown in FIG. 4B, the input of the SHIFT-DR signal makes the third selector 30 in FIG. 3 select the IN-Data; accordingly, the information of the IN-Data as shown in FIG. 4E appears at the TDO as shown in FIG. 4F, which can be read out together with the Pass-Data being the test data input.

Third Embodiment

Next, the third embodiment of the invention will be described with reference to the drawings.

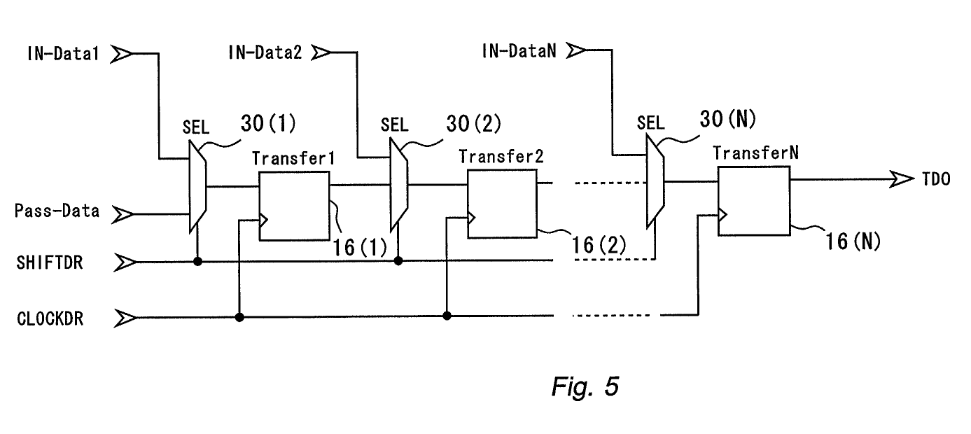

FIG. 5 is a block diagram illustrating the configuration of the TR 16 and 26 that constitute the major part of the third embodiment, and the signal paths to these components.

Here, in FIG. 5, the symbols of the TR are illustrated in correspondence with the logic 1 as an example. That is, in FIG. 5, 16(1), 16(2), . . . 16(N) each denote the TR of plural bits, and 30(1), 30(2), . . . 30(N) denote the third selectors provided on the inputs of the TR 16(1), TR 16(2), . . . TR 16(N). The functions and input signals of the selectors, and so forth are equivalent to those of the third selector 30 in the second embodiment.

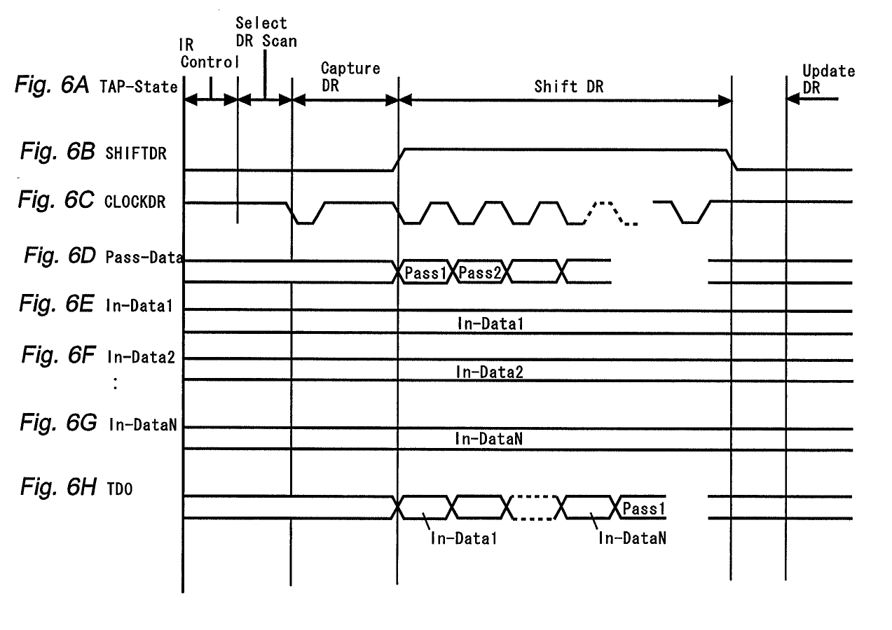

FIG. 6 illustrates, in the same manner as FIG. 4, waveforms in correspondence with the mode transition of the TAP controller, and plural arbitrary information as shown in FIG. 6E through FIG. 6G are prepared as the IN-Data. As shown in FIG. 6B, the input of the SHIFT-DR signal makes the third selectors 30(1), 30(2), . . . 30(N) of each bit in FIG. 5 sequentially select the IN-Data; accordingly, the information of the IN-Data as shown in FIG. 6E through FIG. 6G appear sequentially at the TDO as shown in FIG. 6H, which can be read out together with the Pass-Data being the test data input.

This embodiment is designed to be able to add arbitrary information inherent to each of the logics by each bit as mentioned above, and it is accordingly possible to attain N-fold information, as compared to the second embodiment.

Fourth Embodiment

Next, the fourth embodiment of the invention will be described with reference to the drawings.

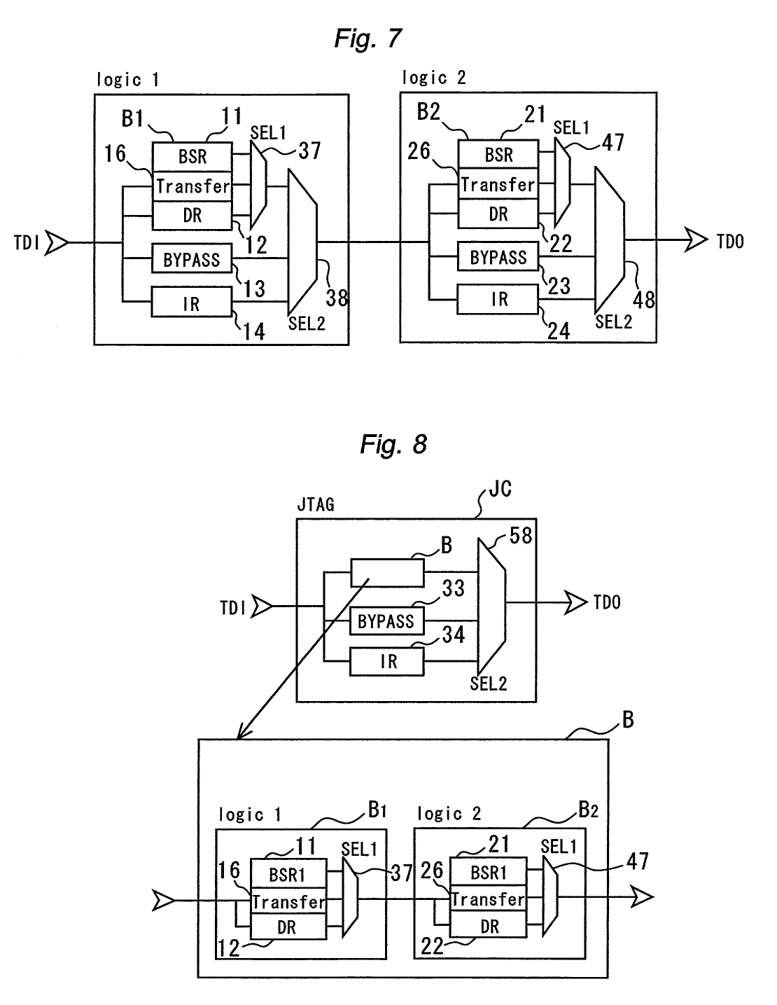

FIG. 7 and FIG. 8 illustrate the configuration of the fourth embodiment. In these figures, the same or the equivalent parts to FIG. 1 are given the same symbols to omit the explanations.

In FIG. 7, B1 signifies a first control block of logic 1 including the BSR 11, TR 16, DR 12, and a first selector 37 that is connected to these registers and controlled by the DR 12. Reference numeral 38 signifies a second selector that is connected to the first selector 37, BR 13, and IR 14, and is selectively controlled by the IR 14. B2 signifies a second control block of logic 2 including the BSR 21, TR 26, DR 22, and a first selector 47 that is connected to these registers and controlled by the DR 22. Reference numeral 48 signifies a second selector that is connected to the first selector 47, BR 23, and IR 24, and is selectively controlled by the IR 24.

This embodiment provides the logic 1, logic 2 with the control blocks B1 and B2, respectively, to thereby separate the JTAG circuit from the logics. This configuration realizes a circuit configuration, for example, as shown in FIG. 8. In this FIG. 8, JC is a JTAG circuit that includes a control block B, a BSR 33, an IR 34, and a selector 58 that is connected to these and controlled by the IR 34. Further, the control block B includes, as the arrow shows the detailed construction, the control block B1 corresponding to the logic 1 and the control block B2 corresponding to the logic 2.

Thus, the BR 33 and the IR 34 and the selector 58 function as the common components to both the blocks B1, B2.

With this configuration, one JTAG circuit will implement a simultaneous testing of plural logics.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-224899, filed on Jul. 25, 2001 including specification, claims, drawings and summary, on which the Convention priority of the present application is based, are incorporated herein by reference in its entirety.

1. A testing device of a semiconductor integrated circuit having more than one different logics and JTAG circuits built in, which executes an in-circuit test of said logics, wherein
the JTAG circuit includes a boundary scan register that executes a test of said logic in accordance with a test data input and stores a test result; a data register; a pseudo bypass register having a bypassing function of said test data input; a first selector connected to said data register and said pseudo bypass register, which selectively takes out outputs of said registers; a bypass register having a bypassing function of said test data input; an instruction register for giving an operation command; and a second selector that is connected to said boundary scan register, said first selector, said bypass register, and said instruction register, which is selectively controlled by said instruction register, and
the JTAG circuits are provided to each of said logics, and the output from said second selector of a specific logic is an input of another logic.

2. A testing device of a semiconductor integrated circuit according to claim 1, wherein said pseudo bypass register is controlled by said data register selecting said first selector.

3. A testing device of a semiconductor integrated circuit according to claim 1, wherein said pseudo bypass register has the same configuration as that of said bypass register.

4. A testing device of a semiconductor integrated circuit according to claim 1, wherein said pseudo bypass register has a selector provided on the input thereof, whereby the test data input to be bypassed and arbitrary information can be inputted selectively.

5. A testing device of a semiconductor integrated circuit according to claim 1, wherein said pseudo bypass register is configured with plural bits, whereby the test data input to be bypassed through the selector and arbitrary information can be inputted selectively by each bit.

6. A testing device of a semiconductor integrated circuit having more than one different logics and JTAG circuits built in, which executes an in-circuit test of said logics, wherein:
each of said logics is provided with: a control block including a boundary scan register that executes a test of said logic in accordance with a test data input and stores a test result, a data register, a pseudo bypass register having a bypassing function of said test data input, and a first selector connected to each of said registers, which selectively takes out outputs of said registers; and a bypass register; an instruction register; and a second selector that is connected to these registers and said first selector, which is selectively controlled by said instruction register, and
the output from the second selector of a specific logic is an input of another logic.

7. A testing device of a semiconductor integrated circuit having more than one different logics and JTAG circuits built in, which executes an in-circuit test of said logics, wherein:
each of said logics is provided with: a control block including a boundary scan register that executes a test of said logic in accordance with a test data input and stores a test result, a data register, a pseudo bypass register having a bypassing function of said test data input, and a first selector connected to each of said registers, which selectively takes out outputs of said registers; a bypass register and an instruction register that are common to each of said control blocks; and a second selector connected to said each control block, said bypass register and said instruction register, which is selectively controlled by the instruction register, and
the output from the first selector of a specific control block is an input of another control block.

8. A test method of a semiconductor integrated circuit, which carries out an in-circuit test thereof by a testing device thereof, according to any one of claims 1 to 7.
